(19) United States
(12) Patent Application Publication
(10) Pub. No.: US 2024/0341123 A1
(43) Pub. Date: Oct. 10, 2024

(54) DISPLAY DEVICE

(71) Applicant: Japan Display Inc., Tokyo (JP)

(72) Inventors: Hiroshi TABATAKE, Tokyo (JP); Kazuyuki HARADA, Tokyo (JP)

(73) Assignee: Japan Display Inc., Tokyo (JP)

(21) Appl. No.: 18/624,516

(22) Filed: Apr. 2, 2024

(30) Foreign Application Priority Data
Apr. 7, 2023 (JP) 2023-062834

(51) Int. Cl. H10K 59/122; H10K 59/131; H10K 59/35; H10K 59/80

(52) U.S. Cl. CPC H10K 59/122; H10K 59/131; H10K 59/352; H10K 59/873

(57) ABSTRACT

According to one embodiment, a display device includes a substrate, an insulating layer disposed above the substrate, a lower electrode disposed above the insulating layer, a rib formed of an inorganic material, including a pixel aperture overlapping the lower electrode and covering a peripheral edge of the lower electrode, a partition disposed above the rib, an upper electrode opposing the lower electrode, and an organic layer disposed between the lower electrode and the upper electrode, which emits light in response to a potential difference between the lower electrode and the upper electrode. The peripheral edge of the lower electrode is located between the insulating layer and the partition in a thickness direction of the insulating layer.

### CROSS-REFERENCE TO RELATED APPLICATION

This application is based upon and claims the benefit of priority from Japanese Patent Application No. 2023-062834, filed Apr. 7, 2023, the entire contents of which are incorporated herein by reference.

### FIELD

Embodiments described herein relate generally to a display device.

### BACKGROUND

In recent years, display devices in which organic light-emitting diodes (OLEDs) are applied as display elements have been put to practical use. Such a display device comprises a lower electrode, an organic layer which covers the lower electrode, and an upper electrode which covers the organic layer.

Generally, organic layers have low resistance to moisture. Therefore, if moisture reaches an organic layer for some reason, it can be a contributing factor to a decrease in display quality, such as a decrease in luminance of the display element when emitting light.

### BRIEF DESCRIPTION OF THE DRAWINGS

FIG. 1 is a diagram showing a configuration example of a display device according to one embodiment.

FIG. 2 is a diagram showing an example of layout of subpixels.

FIG. 3 is a cross-sectional view schematically showing the display device taken along line III-III in FIG. 2.

FIG. 4 is an enlarged plan view schematically showing a part of FIG. 2.

FIG. 5 is a cross-sectional view schematically showing the display device taken along line V-V in FIG. 4.

FIG. 6 is a cross-sectional view schematically showing the display device taken along line VI-VI in FIG. 4.

FIG. 7 is a cross-sectional view schematically showing a display device according to a comparative example.

### DETAILED DESCRIPTION

In general, according to one embodiment, a display device includes a substrate, an insulating layer disposed above the substrate, a lower electrode disposed above the insulating layer, a rib formed of an inorganic material, including a pixel aperture overlapping the lower electrode and covering a peripheral edge of the lower electrode, a partition disposed above the rib, an upper electrode opposing the lower electrode, and an organic layer disposed between the lower electrode and the upper electrode, which emits light in response to a potential difference between the lower electrode and the upper electrode. The peripheral edge of the lower electrode is located between the insulating layer and the partition in a thickness direction of the insulating layer.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the sizes, shapes, etc., of the respective parts are schematically illustrated in the drawings, compared to the actual modes. Besides, in the drawings, the corresponding elements are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction, a direction along the Y axis is referred to as a second direction, and a direction along the Z axis is referred to as a third direction. The third direction Z is a normal direction to a plane containing the first direction X and the second direction Y. Further, viewing the elements parallel to the third direction Z is referred to as plan view.

The display device according to this embodiment is an organic electroluminescent display device comprising an organic light emitting diode (OLED) as a display element, and can be mounted on various types of electronic devices such as television devices, personal computers, in-vehicle devices, tablet terminals, smartphones, mobile telephone terminals, wearable terminals and the like.

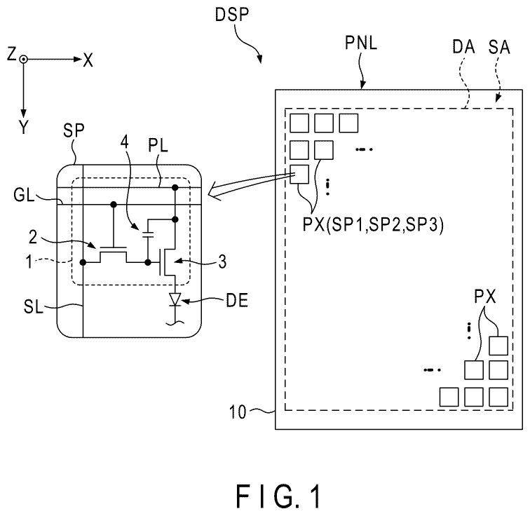

FIG. 1 is a diagram showing a configuration example of a display device DSP according to this embodiment. The display device DSP comprises a display panel PNL including an insulating substrate 10. The display panel PNL includes a display area DA on which images are displayed and a peripheral area SA around the display area DA. The substrate 10 may be of glass or a flexible resin film.

In this embodiment, the shape of the substrate 10 in plan view is rectangular. However, the shape of the substrate 10 in plan view is not limited to rectangular, but may as well be some other shape such as a square, circle, oval or the like.

The display area DA comprises a plurality of pixels PX arranged in a matrix along the first direction X and the second direction Y. The pixels PX each include a plurality of subpixels SP. For example, each pixel PX includes a blue subpixel SP1, a green subpixel SP2, and a red subpixel SP3. Note that the pixel PX may as well include a subpixel SP of some other color, such as white, in addition to the subpixels SP1, SP2 and SP3, or in place of any of the subpixels SP1, SP2 and SP3.

The subpixels SP each comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements each constituted by a thin-film transistor, for example.

A gate electrode of the pixel switch 2 is connected to a respective scanning line GL. One of source and drain electrodes of the pixel switch 2 is connected to a respective signal line SL, and the other is connected to the gate electrode of the drive transistor 3 and the capacitor 4. In the drive transistor 3, one of the source electrode and the drain electrode is connected to the power line PL and capacitor 4, and the other is connected to the display element DE.

Note that the configuration of the pixel circuit 1 is not limited to that of the example illustrated in the figure. For example, the pixel circuit 1 may comprise more thin-film transistors and capacitors.

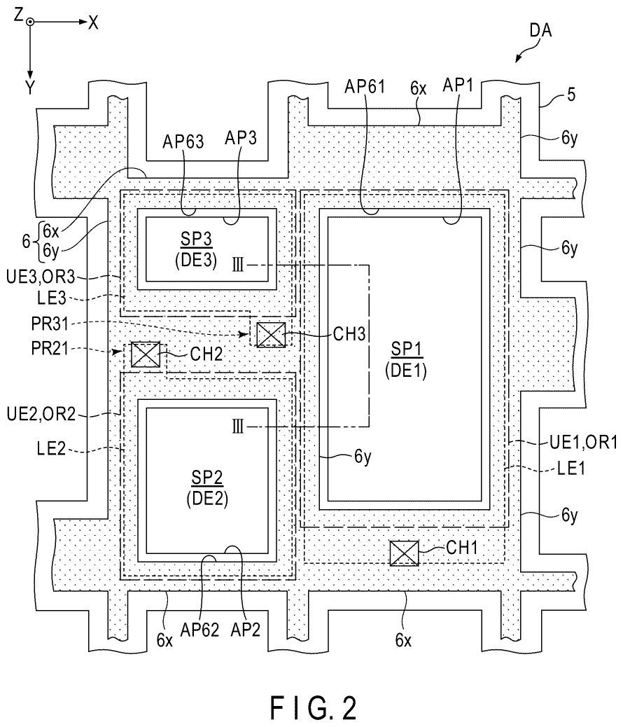

FIG. 2 is a plan view schematically showing an example layout of the subpixels SP1, SP2 and SP3. In the example illustrated in FIG. 2, the subpixels SP2 and SP3 are each aligned with the subpixel SP1 along the first direction X. Further, the subpixel SP2 and the subpixel SP3 are aligned along the second direction Y.

When the subpixels SP1, SP2 and SP3 are laid out as such, rows in each of which subpixels SP2 and SP3 are arranged alternately along the second direction Y and rows in each of which a plurality of subpixels SP1 are repeatedly arranged along the second direction Y are formed in the display area DA. These rows are alternately arranged along the first direction X. Note that the layout of the subpixels SP1, SP2 and SP3 is not limited to that of the example illustrated in FIG. 2.

In the display area DA, a rib 5 and a partition 6 are disposed. The rib 5 includes pixel apertures AP1, AP2 and AP3 in the subpixels SP1, SP2 and SP3, respectively, and has a grid-like shape in plan view. In the example illustrated in FIG. 2, the pixel aperture AP1 is larger than the pixel aperture AP2, and the pixel aperture AP2 is larger than the pixel aperture AP3.

The subpixels SP1 each comprise a lower electrode LE1, an upper electrode UE1 and an organic layer OR1, which overlap the respective pixel aperture AP1. The subpixels SP2 each comprise a lower electrode LE2, an upper electrode UE2, and an organic layer OR2, which overlap the respective pixel aperture AP2. The subpixel SP3 has a lower electrode LE3, an upper electrode UE3, and an organic layer OR3, which overlap the respective pixel aperture AP3.

Parts of the lower electrode LE1, the upper electrode UE1 and the organic layer OR1, which overlap the pixel aperture AP1 constitute a display element DE1 of the subpixel SP1. Parts of the lower electrode LE2, the upper electrode UE2, and the organic layer OR2, which overlap the pixel aperture AP2 constitute a display element DE2 of the subpixel SP2. Parts of the lower electrode LE3, the upper electrode UE3 and the organic layer OR3, which overlap the pixel aperture AP3 constitute a display element DE3 of the subpixel SP3. The display elements DE1, DE2 and DE3 may as well further include a cap layer as described below. The rib 5 surrounds each of these display elements DE1, DE2 and DE3.

The lower electrode LE1 is connected to the pixel circuit 1 of the subpixel SP1 (see FIG. 1) via a contact hole CH1. The lower electrode LE2 is connected to the pixel circuit 1 of the subpixel SP2 via a contact hole CH2. The lower electrode LE3 is connected to the pixel circuit 1 of the subpixel SP3 via a contact hole CH3.

On the rib 5, a partition 6 is disposed. The partition 6 includes a plurality of first partitions 6x extending along the first direction X and a plurality of second partitions 6y extending along the second direction Y. Further, the partition 6 includes apertures AP61, AP62 and AP63 in the subpixels SP1, SP2 and SP3, respectively. That is, the partition 6, as in the case of the rib 5, has a grid-like shape in plan view, and both the rib 5 and the partition 6 are disposed between the display elements DE1, DE2 and DE3.

In the example of FIG. 2, the lower electrodes LE2 and LE3 include projecting portions PR21 and PR31, respectively. The projecting portion PR21 protrudes from the main body of the lower electrode LE2 (, which is the part overlapping the pixel aperture AP2) toward the contact hole CH2. The projecting portion PR31 protrudes from the main body of the lower electrode LE2 (, which is the part overlapping the pixel aperture AP3) toward the contact hole CH3. The contact holes CH2 and CH3 overlap the projecting portions PR21 and PR31, respectively.

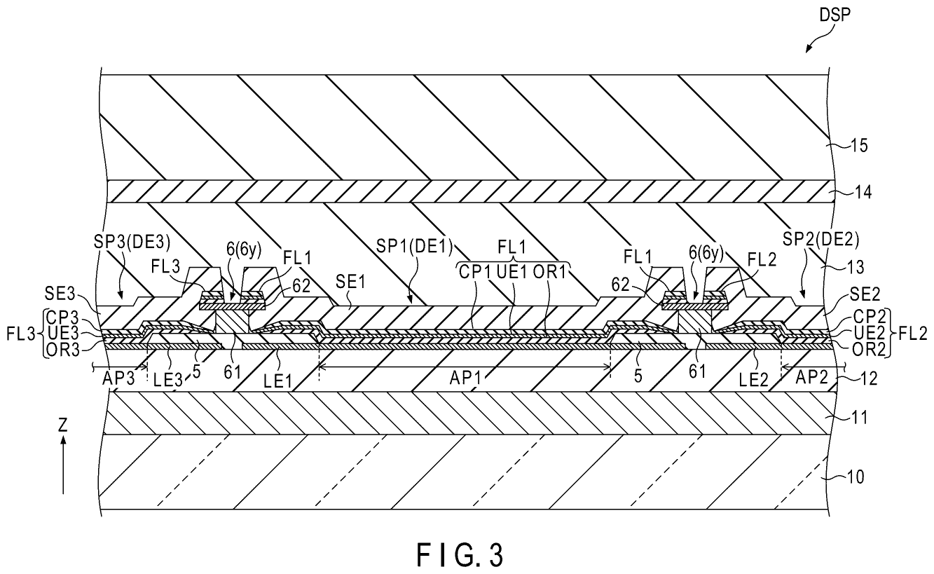

FIG. 3 is a cross-sectional view schematically showing the display device DSP taken along line III-III in FIG. 2. On the substrate 10 described above, a circuit layer 11 is placed. The circuit layer 11 includes various circuits and wiring lines, such as the pixel circuit 1, the scanning lines GL, the signal lines SL, the power line PL and the like, shown in FIG. 1.

The circuit layer 11 is covered by an insulating layer 12. The insulating layer 12 functions as a planarization film that planarizes the unevenness caused by the circuit layer 11. Although not illustrated in the cross section shown in FIG. 3, the contact holes CH1, CH2 and CH3 described above are formed in the insulating layer 12.

The lower electrodes LE1, LE2 and LE3 are disposed on the insulating layer 12. The rib 5 is disposed on the insulating layer 12 and the lower electrodes LE1, LE2 and LE3. End portions of the lower electrodes LE1, LE2 and LE3 are covered by the rib 5.

The partition 6 (the second partitions 6y) comprises a conductive lower portion 61 disposed on the rib 5, and a upper portion 62 disposed on the lower portion 61. The upper portion 62 has a width greater than that of the lower portion 61. With this configuration, both ends of the upper portion 62 protrude from side surfaces of the lower portion 61. The shape of the partition 6 having such a configuration is referred to as an overhang shape.

The organic layer ORI covers the lower electrode LE1 through the pixel aperture AP1. The upper electrode UE1 covers the organic layer OR1 and opposes the lower electrode LE1. The organic layer OR2 covers the lower electrode LE2 through the pixel aperture AP2. The upper electrode UE2 covers the organic layer OR2 and opposes the lower electrode LE2. The organic layer OR3 covers the lower electrode LE3 through the pixel aperture AP3. The upper electrode UE3 covers the organic layer OR3 and opposes the lower electrode LE3. The upper electrodes UE1, UE2 and UE3 are in contact with a side surface of the lower portion 61 of the partition 6.

In the example in FIG. 3, a cap layer CP1 is placed on the upper electrode UE1, a cap layer CP2 is placed on the upper electrode UE2, and a cap layer CP3 is placed on the upper electrode UE3. The cap layers CP1, CP2 and CP3 have a function as optical adjustment layers that improve the efficiency of extraction of light emitted by the organic layers OR1, OR2 and OR3, respectively.

In the following descriptions, a stacked body including the organic layer OR1, the upper electrode UE1, and the cap layer CP1 is referred to as a stacked layer film FL1, a stacked body including the organic layer OR2, the upper electrode UE2, and the cap layer CP2 is referred to as a stacked layer film FL2, and a stacked body including the organic layer OR3, the upper electrode UE3, and the cap layer CP3 is referred to as a stacked layer film FL3.

A part of the stacked layer film FL1 is located above the upper portion 62. This part of the thin film FL1 is separated from the portion of the stacked layer film FL1 that is located under the partition 6 (the portion constituting the display element DE1). Similarly, a part of the stacked layer film FL2 is located above the upper portion 62, and this part of the stacked layer film FL2 is separated from the portion of the stacked layer film FL2 that is located under the partition 6 (the part constituting the display element DE2). Further, a part of the stacked layer film FL3 is located above the upper portion 62 and this part is separated from the portion of the stacked layer film FL3 that is located under the partition 6 (the portion constituting the display element DE3).

In the subpixels SP1, SP2 and SP3, sealing layers SE1, SE2 and SE3 are disposed, respectively. The sealing layer SE1 continuously covers the partition 6 around the stacked layer film FL1 and the subpixel SP1. The sealing layer SE2 continuously covers the partition 6 around the stacked layer film FL2 and the subpixel SP2. The sealing layer SE3 continuously covers the partition 6 around the thin film FL3 and the subpixel SP3.

In the example illustrated in FIG. 3, the stacked layer film FL1 and the sealing layer SE1 located on the portion of the partition 6 between the subpixels SP1 and SP2 are separated from the stacked layer film FL2 and the sealing layer SE2 on the partition 6. Further, the stacked layer film FL1 and the sealing layer SE1 located on the portion of the partition 6 between the subpixels SP1 and SP3 are separated from the stacked layer film FL3 and the sealing layer SE3 on the partition 6.

The sealing layers SE1, SE2 and SE3 are covered by a resin layer 13. The resin layer 13 is covered by a sealing layer 14. The sealing layer 14 is covered by a resin layer 15. The resin layers 13 and 15 and the sealing layer 14 are continuously provided at least over the entire display area DA, and a part of the resin layers extend to the peripheral area SA.

A cover member such as a polarizer, a touch panel, a protective film or a cover glass may be further disposed above the resin layer 15. Such a cover member may be adhered to the resin layer 15 via an adhesive layer such as optical clear adhesive (OCA), for example.

The organic insulating layer 12 is formed of an organic insulating material. The rib 5, the sealing layers 14, SE1, SE2 and SE3 each can be formed of an inorganic insulating material such as silicon nitride (SiN), silicon oxide (SiO), silicon oxynitride (SiON), aluminum oxide (Al₂O₃) or the like. For example, the rib 5 is formed of silicon oxynitride, whereas the sealing layers 14, SE1, SE2 and SE3 are formed of silicon nitride. The resin layers 13 and 15 are formed of a resin material (organic insulating material) such as epoxy resin or acrylic resin.

The lower electrodes LE1, LE2 and LE3 each include a reflective layer formed of silver (Ag), for example, and a pair of conductive oxide layers which respectively cover the upper and lower surfaces of the reflective layer. Each conductive oxide layer can be formed of a transparent conductive oxide, such as indium tin oxide (ITO), indium zinc oxide (IZO) or indium gallium zinc oxide (IGZO).

The upper electrodes UE1, UE2 and UE3 are formed, for example, of a metallic material such as an alloy of magnesium and silver (MgAg). For example, the lower electrodes LE1, LE2 and LE3 correspond to anodes, and the upper electrodes UE1, UE2 and UE3 correspond to cathodes.

The organic layers OR1, OR2 and OR3 each have a stacked layer structure of, for example, a hole injection layer, a hole transport layer, an electron blocking layer, a light emitting layer, a hole blocking layer, an electron transport layer and an electron injection layer. The organic layers OR1, OR2 and OR3 may have a so-called tandem structure including a plurality of light emitting layers.

The cap layers CP1, CP2 and CP3 each have, for example, a stacked layer structure in which a plurality of transparent thin films are stacked one on another. These thin films may include thin films formed of inorganic materials and thin films formed of organic materials. Further, these plurality of thin films have refractive indices different from each other. The materials of the thin films are different from the materials of the upper electrodes UE1, UE2 and UE3, and also different from the materials of the sealing layers SE1, SE2 and SE3. Note that at least one of the cap layers CP1, CP2 and CP3 may be omitted.

The lower portion 61 of the partition is formed of, for example, aluminum (Al). The lower portion 61 may as well be formed of an aluminum alloy such as an aluminum-neodymium alloy (AlNd), an aluminum-yttrium alloy (AlY), or an aluminum-silicon alloy (AlSi), or may have a stacked layer structure of an aluminum layer and an aluminum alloy layer. Further, the lower portion 61 may as well include a bottom layer formed of a metallic material different from aluminum or the aluminum alloy, under the aluminum layer or the aluminum alloy layer. Usable examples of the metallic material which forms the bottom layer include molybdenum (Mo), titanium nitride (TiN), molybdenum-tungsten alloy (MoW) and molybdenum-niobium alloy (MoNb).

For example, the upper portion 62 of the partition 6 has a stacked layer structure of a bottom layer formed of a metallic material and a top layer formed of a conductive oxide. Usable examples of the metallic material which forms the bottom layer include titanium, titanium nitride, molybdenum, tungsten, molybdenum-tungsten alloy, and molybdenum-niobium alloy. Usable examples of the conductive oxide which forms the top layer include ITO and IZO. Note that the upper portion 62 may have a single-layer structure of any of these materials.

To the partition 6, a common voltage is supplied. This common voltage is supplied to each of the upper electrodes UE1, UE2 and UE3, which are in contact with a side surface of the lower portion 61. To the lower electrodes LE1, LE2 and LE3, pixel voltages are respectively supplied through the respective pixel circuits 1 of the subpixels SP1, SP2 and SP3.

The organic layers OR1, OR2 and OR3 emit light in response to the voltage applied. More specifically, when a potential difference is created between the lower electrode LE1 and the upper electrode UE1, the light emitting layer of the organic layer OR1 emits light of the blue wavelength range. When a potential difference is created between the lower electrode LE2 and the upper electrode UE2, the light emitting layer of the organic layer OR2 emits light of the green wavelength range. When a potential difference is created between the lower electrode LE3 and the upper electrode UE3, the light emitting layer of the organic layer OR3 emits light of the red wavelength range.

As another example, the light emitting layers of the organic layers OR1, OR2 and OR3 may emit light of the same color (for example, white). In this case, the display device DSP may comprise color filters that converts the light emitted by the light emitting layers into light of a color corresponding to each respective one of the subpixels SP1, SP2 and SP3. Further, the display device DSP may as well comprise a layer containing quantum dots that are excited by the light emitted by the light emitting layers to generate light of colors corresponding to the subpixels SP1, SP2 and SP3, respectively.

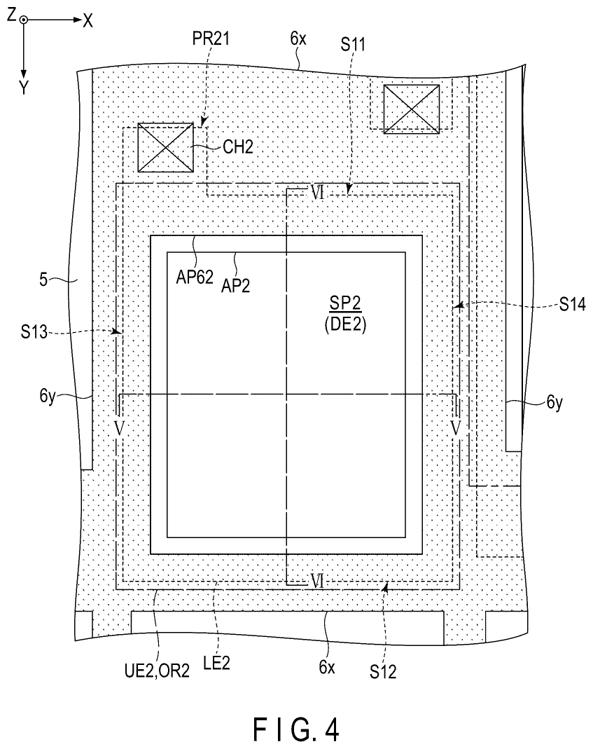

FIG. 4 is an enlarged plan view schematically showing the vicinity of the subpixel SP2 in FIG. 2.

The peripheral edge (outline) of the lower electrode LE2 has a first side S11, a second side S12, a third side S13 and a fourth side S14. The first side S11 extends along the first direction X. The second side S12 is located on a side opposite to the first side S11 in the second direction Y and extends along the first direction X. The third side S13 extends along the second direction Y. The fourth side S14 is located on a side opposite to the third side S13 in the first direction X and extends along the second direction Y.

The first side S11, the second side S12, the third side S13, and the fourth side S14 are each located on an outer side of the aperture AP62 and surrounds the aperture AP62. The first side S11, the second side S12, the third side S13, and the fourth side S14 each overlap the partition 6. For example, the first side S11 overlaps the first partition 6x illustrated in the upper part of the figure. The second side S12 overlaps the first partition 6x shown in the lower part in the figure. The third side S13 overlaps the second partition 6y shown on the left part in the figure. The fourth side S14 overlaps the second partition 6y shown on the right part of the figure. Note that the projecting portion PR21 protrudes from the first side S11 upwardly in the figure and overlaps the contact hole CH2.

Although not represented in FIG. 4, similarly, the peripheral edges of the lower electrodes LE1 and LE3 are located on outer sides of the apertures AP61 and AP63 so as to surround the apertures AP61 and AP63, respectively, and overlap the partition 6 (the first partition 6x and second partition 6y, respectively).

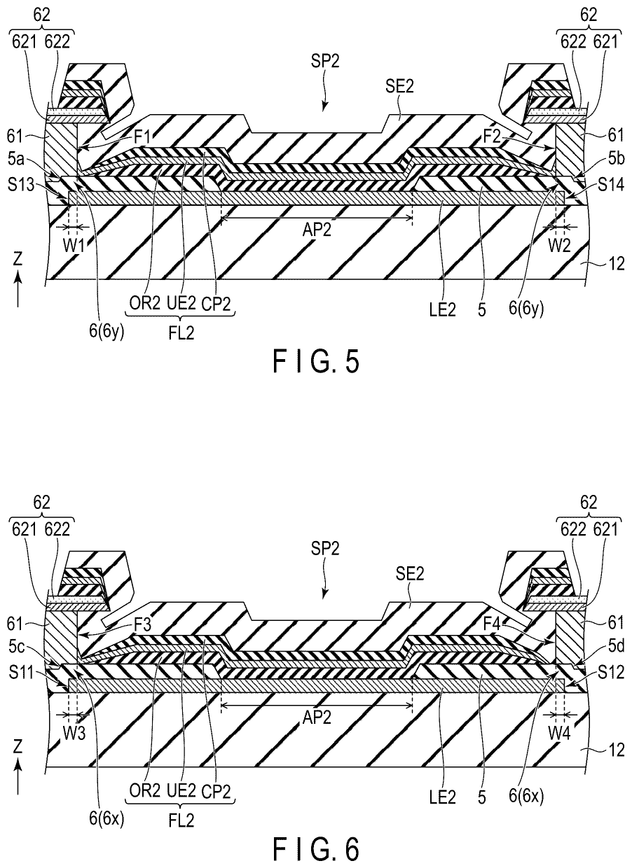

FIG. 5 is a cross-sectional view schematically showing the display device DSP taken along line V-V in FIG. 4. FIG. 6 is a cross-sectional view schematically showing the display device DSP taken along line VI-VI in FIG. 4. In FIGS. 5 and 6, the substrate 10, the circuit layer 11, the resin layers 13 and 15, and the sealing layer 14 are omitted.

In the example of FIG. 5, the lower portion 61 of the partition 6 on the left side in the figure (the second partition 6y) includes a side surface F1 and the lower portion 61 of the partition 6 on the right side in the figure (the second partition 6y) includes a side surface F2. The peripheral edges of the upper electrode UE2 are in contact with the side surfaces F1 and F2, respectively.

Similarly, in the example of FIG. 6, the lower portion 61 of the partition 6 on the left side of the figure (the first partition 6x) includes a side surface F3 and the lower portion 61 of the partition 6 on the right side in the figure (the first partition 6x) includes a side surface F4. One of the peripheral edges of the upper electrode UE2 is in contact with the side surface F3 and the other is not in contact with the side surface F4.

FIGS. 5 and 6 respectively show cases where one of the peripheral edges of the upper electrode UE2 is not contact with the side surface F4 only. However, it suffices if the peripheral edge of the upper electrode UE2 is brought into contact with at least the side surface F3, and does not necessarily be in contact with the side surfaces F1 and F2. More precisely, it suffices if at least the one of the peripheral edges of the upper electrode UE2, which is close to the contact hole CH2 is in contact with the side surface of the lower portion 61, and the other edges need not be in contact with the side surface of the lower portion 61.

Although not represented in FIGS. 5 and 6, similarly, it suffices if at least those of the peripheral edges of the upper electrodes UE1 and UE3, which are close to the contact holes CH1 and CH3 are in contact with the respective side surfaces of the lower portion 61, and the other edges need not be in contact with the side surfaces of the lower portion 61.

Since the rib 5 is thin in this embodiment, a step is formed in the upper surface of the rib 5 due to the lower electrodes LE1, LE2 and LE3. For example, in the example of FIG. 5, a step 5a is formed in the rib 5 in the vicinity of the third side S13 of the lower electrode LE2. Similarly, a step 5b is formed in the rib 5 in the vicinity of the fourth side S14 of the lower electrode LE2.

Further, in the example of FIG. 6, for example, a step 5c is formed in the rib 5 in the vicinity of the first side S11 of the lower electrode LE2. Similarly, a step 5d is formed in the rib 5 in the vicinity of the second side S12 of the lower electrode LE2.

In this embodiment, as shown in FIGS. 5 and 6, the peripheral edges of the lower electrode LE2 overlap the lower portion 61 of the partition 6.

More particularly, the third side S13 and the fourth side S14 of the peripheral edges of the lower electrode LE2 overlap the lower portion 61 of the second partition 6y, which constitutes the partition 6. That is, as shown in FIG. 5, the third side S13 and the fourth side S14 are located between the organic insulating layer 12 and the lower portion 61 of the second partition 6y in the third direction Z (the thickness direction of the rib 5 and the organic insulating layer 12). With this configuration, the step 5a created by the third side S13 and the step 5b created by the fourth side S14 are covered by the lower portion 61 of the second partition 6y.

Note that the overlapping width between the lower electrode LE2 and the lower portion 61 of the second partition 6y (more specifically, a width W1 from the third side S13 to the side surface F1 and a width W2 from the fourth side S14 to the side surface F2) should preferably be 1.5 μm or more. With this configuration, even if some variation in the size of the second partition 6y occurs during the process of forming the partition 6, the peripheral edges of the lower electrode LE2 can be reliably positioned between the organic insulating layer 12 and the lower portion 61 of the second partition 6y in the third direction Z.

Similarly, the first side S11 and the second side S12 of the lower electrode LE2 overlap the lower portion 61 of the first partition 6x, which constitutes the partition 6. That is, as shown in FIG. 6, the first side S11 and the second side S12 are located between the organic insulating layer 12 and the lower portion 61 of the first partition 6x in the third direction Z. With this configuration, the step 5c created by the first side S11 and the step 5d created by the second side S12 are covered by the lower portion 61 of the first partition 6x.

Note that the overlapping width between the lower electrode LE2 and the lower portion 61 of the second partition 6x (more specifically, a width W3 from the first side S11 to the side surface F3 and a width W4 from the second side S12 to the side surface F4) should preferably be 1.5 μm or more. With this configuration, even if some variation in the size of the first partition 6x occurs during the process of forming the partition 6, the peripheral edges of the lower electrode LE2 can be reliably positioned between the organic insulating layer 12 and the lower portion 61 of the first partition 6x in the third direction Z.

Although not represented in FIGS. 5 and 6, similarly, the peripheral edges of the lower electrodes LE1 and LE3 overlap the lower portion 61 of the partition 6, and the peripheral edges of the lower electrodes LE1 and LE3 are located between the organic insulating layer 12 and the lower portion 61 of the partition 6 in the third direction Z. Therefore, the step of the rib 5 caused by the lower electrodes LE1 and LE3 can as well be covered by the lower portion 61 of the partition 6.

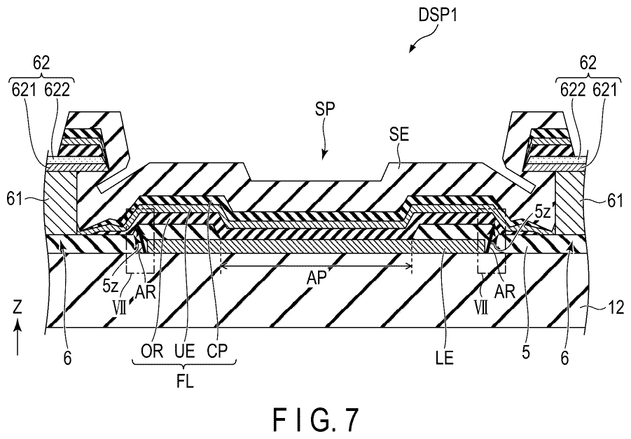

According to the display device DSP of this embodiment, it is possible to improve resistance to moisture. This advantageous effect will now be explained using FIG. 7.

FIG. 7 is a cross-sectional view schematically showing a display device DSP1 according to a comparative example. The display device DSP1 according to the comparative example differs from the display device DSP of the present embodiment in that the peripheral edges of the lower electrode LE are not located between the organic insulating layer 12 and the lower portion 61 of the partition 6 in the third direction Z.

As described above, the rib 5 is thin, and therefore a step 5z is formed in the upper surface of the rib 5 due to the lower electrode LE. In the vicinity of the step 5z with such configuration, defects such as cracks, for example, are likely to occur in the rib 5. In the display device DSP1 according to the comparative example, when some defect occurs in the rib 5 in the area near the step 5z surrounded by the chain line frame VII as shown in FIG. 7, moisture that has penetrated through the organic insulating layer 12 to the area near the step 5z may enter the organic layer OR through the defect created in the rib 5 (see arrow AR in FIG. 7).

By contrast, in the display device DSP of this embodiment, the peripheral edges of the lower electrodes LE (more specifically, the lower electrodes LE1, LE2 and LE3) are located between the organic insulating layer 12 and the partition 6 (lower portion 61), and steps (more specifically, steps 5a, 5b, 5c and 5d) of the rib 5 caused by the lower electrodes LE are covered by the partition 6. With this configuration, even if some defects occurs in the vicinity of the steps of the rib 5 caused by the lower electrodes LE, such defects are covered by the partition 6. Therefore, moisture that has penetrated through the organic insulating layer 12 to the vicinity of the steps of the rib 5 can be prevented from entering the organic layer OR from the defects made in the rib 5. That is, the resistance of the display device DSP to moisture is improved.

As explained above, according to this embodiment, it is possible to provide a display device DSP with improved resistance to moisture.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a substrate;
an insulating layer disposed above the substrate;
a lower electrode disposed above the insulating layer;
a rib formed of an inorganic material, including a pixel aperture overlapping the lower electrode and covering a peripheral edge of the lower electrode;
a partition disposed above the rib;
an upper electrode opposing the lower electrode;
an organic layer disposed between the lower electrode and the upper electrode, which emits light in response to a potential difference between the lower electrode and the upper electrode, wherein
the peripheral edge of the lower electrode is located between the insulating layer and the partition in a thickness direction of the insulating layer.

2. The display device of claim 1, wherein
the partition includes a lower portion disposed above the rib and an upper portion disposed above the lower portion and including an end portion protruding from a side surface of the lower portion, and
the peripheral edge of the lower electrode is located between the insulating layer and the lower portion in the thickness direction.

3. The display device of claim 2, wherein
the lower electrode and the lower portion overlap each other with a width of 1.5 μm or more in plan view.

4. The display device of claim 2, wherein
the peripheral edge of the lower electrode surrounds an aperture formed by the end portion of the upper portion in plan view.

5. The display device of claim 1, further comprising:
a pixel circuit disposed between the substrate and the insulating layer,
wherein
the insulating layer comprises a contact hole that overlaps the partition in plan view, and
the lower electrode is connected to the pixel circuit through the contact hole.

6. The display device of claim 5, wherein
a side of the peripheral edge of the upper electrode, which is proximate to the contact hole is in contact with a side surface of the partition.

7. A display device comprising:
a substrate;
an insulating layer disposed above the substrate;
a lower electrode disposed above the insulating layer;
a rib formed of an inorganic material and including a pixel aperture overlapping the lower electrode and covering a peripheral edge of the lower electrode;
a partition disposed above the rib;
an upper electrode opposing the lower electrode;
an organic layer disposed between the lower electrode and the upper electrode, which emits light in response to a potential difference between the lower electrode and the upper electrode, wherein
the partition includes a lower portion formed of a metal disposed on the rib, and an upper portion disposed above the lower portion and including an end portion protruding from a side surface of the lower portion, and
the peripheral edge of the lower electrode overlaps the partition.

8. The display device of claim 7, wherein
the upper portion of the partition has a staked layer structure comprising a bottom layer formed of a metallic material and a top layer formed of a conductive oxide.

9. The display device of claim 8, wherein
the metal of the lower portion of the partition is aluminum or an aluminum alloy.

10. The display device of claim 9, wherein
the lower electrode and the lower portion overlap each other with a width of 1.5 μm or more in plan view.

11. The display device of claim 7, wherein
the peripheral edge of the lower electrode surrounds an aperture formed by the end portion of the upper portion in plan view.

12. The display device of claim 7, further comprising:
a pixel circuit disposed between the substrate and the insulating layer,
wherein
the insulating layer comprises a contact hole that overlaps the partition in plan view, and
the lower electrode is connected to the pixel circuit through the contact hole.

13. A display device comprising:
a substrate;
an insulating layer disposed above the substrate;
a lower electrode disposed above the insulating layer;
a rib formed of an inorganic insulating material, including a pixel aperture overlapping the lower electrode and covering a peripheral edge of the lower electrode;
a partition disposed above the rib;
an upper electrode opposing the lower electrode;
an organic layer disposed between the lower electrode and the upper electrode, which emits light in response to a potential difference between the lower electrode and the upper electrode; and
a sealing layer formed of an inorganic insulating material, which covers the partition and the upper electrode, wherein
the partition includes a lower portion formed of a metal disposed on the rib, and an upper portion disposed above the lower portion and including an end portion protruding from a side surface of the lower portion, and a conductive oxide covering the upper portion of the partition, and
the peripheral edge of the lower electrode overlaps the partition.

14. The display device of claim 13, wherein
the upper portion of the partition is formed of a metallic material.

15. The display device of claim 14, wherein
the metal of the lower portion of the partition is aluminum or an aluminum alloy.

16. The display device of claim 15, wherein
the lower electrode and the lower portion overlap each other with a width of 1.5 μm or more in plan view.

17. The display device of claim 13, wherein
the peripheral edge of the lower electrode surrounds an aperture formed by the end portion of the upper portion in plan view.

18. The display device of claim 13, further comprising:
a pixel circuit disposed between the substrate and the insulating layer,
wherein
the insulating layer comprises a contact hole that overlaps the partition in plan view, and
the lower electrode is connected to the pixel circuit through the contact hole.
